(19) United States
(12) Patent Application Publication
(10) Pub. No.: US 2004/0089630 A1
(43) Pub. Date: May 13, 2004

(54) Surface modification method

(76) Inventors: Shinzo Uchiyama, Ibaraki (JP); Nobumasa Suzuki, Ibaraki (JP); Hideo Kitagawa, Ibaraki (JP)

Correspondence Address: FITZPATRICK CELLA HARPER & SCINTO, 30 ROCKEFELLER PLAZA, NEW YORK, NY, 10112, US

(21) Appl. No.: 10/699,883

(22) Filed: Nov. 4, 2003

(30) Foreign Application Priority Data
Nov. 12, 2002 (JP) 2002-328706

(51) Int. Cl. C23C 16/00; C23F 1/00

(52) U.S. Cl. 216/67; 118/723 R; 427/255.28

(57) ABSTRACT

A method for modifying a surface of a substrate to be processed, by utilizing microwave surface-wave plasma includes the steps of maintaining a temperature of the substrate to a temperature which substantially prevents a material injected by a plasma process into the substrate from diffusing in the substrate, and provides an anneal effect, introducing process gas including the material into a plasma process chamber, generating plasma in the plasma process chamber, and changing at least once an electron temperature of the plasma.

This application claims a benefit of priority based on Japanese Patent Application No. 2002-328706, filed on Nov. 12, 2002, which is hereby incorporated by reference herein in its entirety as if fully set forth herein.

### BACKGROUND OF THE INVENTION

The present invention relates generally to semiconductor manufacture methods, and more particularly to a method that provides high-quality and quick modification to a substrate to be processed, by utilizing microwave surface-wave plasma. The present invention is suitable, for example, for a method for forming a silicon oxynitride film.

Along with recent fine processing of semiconductor devices, a silicon oxynitride film has been applied in a gate insulating film with a thickness below 3 nm. A silicon oxynitride film is made by introducing nitrogen into a silicon oxide film. The silicon oxynitride film has attracted attention due to its excellent characteristics such as high specific permittivity, leak current prevention, and boron diffusion prevention from a gate electrode.

A heat treatment, remote plasma, etc. have been studied as a nitriding process to the silicon oxide film.

One proposed method among those for making a silicon oxynitride film which utilizes a heat treatment, for example, heats up a wafer under nitrogen monoxide gas atmosphere for several hours (62nd Japan Society of Applied Physics, Annual Meeting, Preprint, No. 2, page 630) so as to thermally nitride a silicon oxide film. Thermal nitriding needs such high temperature as 800° C. to 1000° C., so that nitrogen easily moves in a silicon oxide film and reaches an interface between the silicon oxide film and silicon. Since diffusion differs between the silicon oxidation film and silicon, nitrogen accumulates in the interface of the silicon oxide film and silicon. Thus, a nitrogen concentration distribution in a depth direction in the silicon oxide film as a result of thermal nitriding does not locate nitrogen on a surface, and causes increased nitrogen concentration in the interface between silicon and the silicon oxide film.

One proposed method for making a silicon oxynitride film which utilizes the remote plasma sufficiently decreases nitrogen ions in nitrogen plasma, transports only nitrogen active species, and nitrides a silicon oxide film (62nd Japan Society of Applied physics, Annual Meeting, Preprint, No. 2, page 631). This method uses reactive nitrogen active species to nitride a silicon oxide film at comparatively low temperature of about 400° C. It decreases nitrogen ions in nitrogen plasma and uses only nitrogen active species by maintaining a reactor at a high pressure, and spacing plasma generation part from a wafer. The remote plasma process exhibits a large nitrogen concentration distribution in a depth direction in a silicon oxide film near the surface, and small one at the interface between silicon and a silicon oxide film.

These conventional methods for nitriding a silicon oxide film have several disadvantages and have not yet been reduced to practice.

For example, the heat nitriding process has a high nitrogen concentration at the interface of a silicon oxide film and silicon, and causes inferior device characteristics. In addition, processing of a wafer at high temperature such as 800° C. to 1000° C. diffuses materials other than nitrogen and deteriorates device characteristics. It also takes a remarkably long process time.

On the other hand, the remote plasma process cannot obtain sufficient nitrogen active species since necessary nitrogen active species decreased with the nitrogen ions in the plasma, and takes a very long process time. In addition, this process cannot enhance the nitrogen surface density since the nitrogen concentration distribution in a depth direction in the silicon oxide film decreases drastically by depth.

### BRIEF SUMMARY OF THE INVENTION

Accordingly, it is an exemplary object of the present invention to provide a surface modification method, which eliminates the above prior art disadvantages, and provides a superior and rapid surface modification by increasing a concentration of a desired material from a surface to a desired depth in a substrate to be processed.

A method of one aspect of the present invention for modifying a surface of a substrate to be processed, by utilizing microwave surface-wave plasma includes the steps of maintaining a temperature of the substrate to a temperature which substantially prevents a material injected by a plasma process into the substrate from diffusing in the substrate, and provides an anneal effect, introducing process gas including the material into a plasma process chamber, generating plasma in the plasma process chamber, and changing at least once an electron temperature of the plasma.

The changing step may change a pressure of the plasma process chamber, a mixture ratio of the process gas introduced into the plasma process chamber, and/or a distance between a generation part for generating the plasma and a stage for mounting the substrate to be processed.

A method of another aspect of the present invention for modifying a surface of a substrate to be processed by utilizing process gas that includes a predetermined material, and microwave surface-wave plasma includes the steps of turning the process gas into the plasma, injecting the plasma into the substrate, and forming at least two concentration distributions of the material on the surface of the substrate, and maintaining a temperature of the substrate to one which prevents the material from diffusing beyond a predetermined depth in the substrate, and which maintains defect density of the substrate below a permissible value.

Other objects and further features of the present invention will become readily apparent from the following description of the preferred embodiments with reference to accompanying drawings.

### BRIEF DESCRIPTION OF THE DRAWINGS

FIG. 1 is a schematic sectional perspective view of a microwave surface-wave interference plasma processing apparatus as one embodiment according to the present invention.

FIG. 2 is a graph showing a nitrogen concentration distribution in a depth direction in a silicon oxide film formed on a substrate to be processed.

FIG. 3 is a graph showing a nitrogen concentration distribution in a depth direction in a silicon oxide film formed on the substrate to be processed.

FIG. 4 is a graph showing a nitrogen concentration distribution in a depth direction in a silicon oxide film formed on the substrate to be processed.

FIG. 5 is a graph showing a relationship between the pressure in a process chamber and a peak depth of a nitrogen concentration distribution in a silicon oxide film formed on the substrate to be processed.

FIG. 6 is a schematic sectional perspective view of a variation of the microwave surface-wave interference plasma processing apparatus shown in FIG. 1.

FIG. 7 is a schematic perspective view of a preheat chamber applicable to the inventive microwave surface-wave interference plasma processing apparatus.

FIG. 8 is a schematic perspective view for explaining a connection between the process chamber and the preheat chamber shown in FIG. 7.

FIG. 9 is a schematic block diagram of a gas mixture ratio control mechanism applicable to the microwave surface-wave interference plasma processing apparatus shown in FIG. 1.

FIG. 10 is a schematic block diagram of an elevator mechanism of a stage applicable to the microwave surface-wave interference plasma processing apparatus shown in FIG. 1.

### DETAILED DESCRIPTION OF THE PREFERRED EMBODIMENTS

First Embodiment

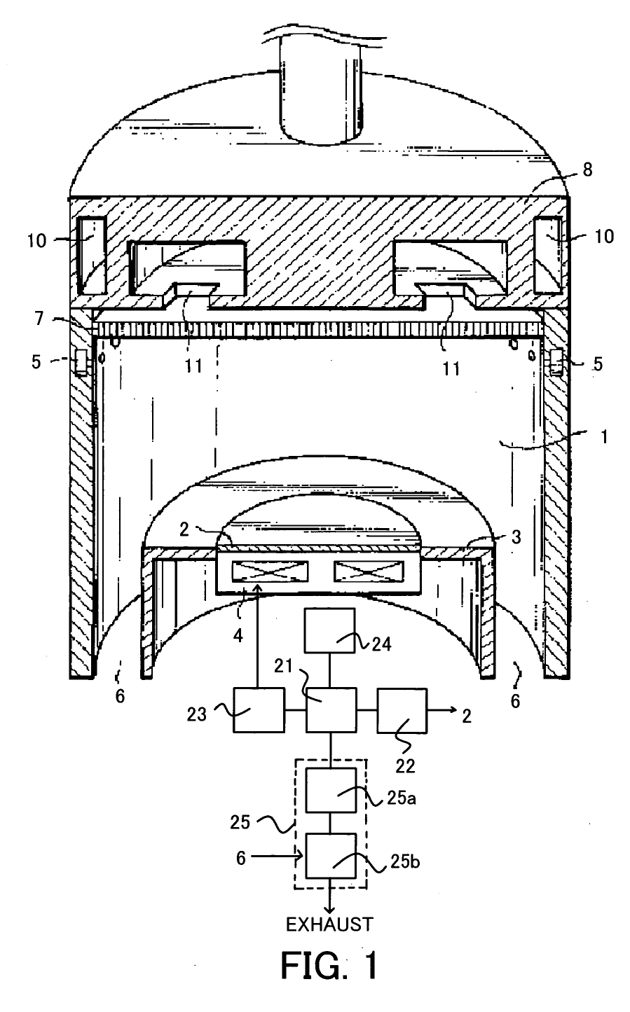

A description will be given of a microwave surface-wave interference plasma processing apparatus of a first embodiment according to the present invention, with reference to FIG. 1. In FIG. 1, 1 is a plasma processing chamber, 2 is a substrate to be processed, 3 is a substrate stage for holding the substrate 2, 4 is a heater, 5 is a process gas introducing means, 6 is an exhaust opening, 8 is a slot-cum non-terminal circle waveguide for introducing microwaves to the plasma process chamber 1, 11 is a slot provided in the slot-cum non-terminal circle waveguide 8 for each ½ or ¼ times a wavelength of an in-tube microwave, 7 is a dielectric window for introducing microwaves to the plasma process chamber 1, and 10 is a cooling channel installed in the slot-cum non-terminal circle waveguide 8. An inner wall of the plasma process chamber 1 and the dielectric window are made of quartz to prevent metallic contamination to the substrate 2. The substrate stage 3 is made of ceramic composed mainly of aluminum nitride for balance between heat conduction and metallic contamination.

In plasma processing, cooling water flows through the cooling channel 10 and cools the slot-cum non-terminal circle waveguide 8 down to the room temperature. The heater 4 heats the substrate stage 3 up to 200° C. The substrate 2 that forms a silicon oxide film having a thickness of 2 nm on its surface is fed to and placed on the stage 3. Next, the plasma process chamber 1 is vacuum-exhausted by an exhaust system 25 that includes a pressure regulating valve 25a and a vacuum pump 25b manufactured, for example, by Kashiyama Industry Co. Ltd., which are known in the art. Then, nitrogen gas is introduced into the plasma process chamber 1 at 200 sccm through the process gas introducing means 5. Then, the pressure regulating valve 25a, such as a conductance valve, provided in the exhaust system 25 is regulated so as to hold the pressure in the plasma process chamber 1 to the first pressure, such as 130 Pa.

Then, the microwave power supply supplies the plasma process chamber 1 with microwaves of 1.5 kW through the slot-cum non-terminal circle waveguide 8 and dielectric window 7, thereby generating plasma in the plasma process chamber 1. Microwaves introduced in the slot-cum non-terminal circle waveguide 8 are distributed to left and right sides, and transmit with an in-tube wavelength longer than that in the free space. They are introduced into the plasma process chamber 1 via the dielectric window through the slot 11, and transmit as a surface wave on the surface of the dielectric window 7. This surface wave interferes between adjacent slots, and forms an electric field, which generates plasma. The plasma generation part has high electron temperature and electron density, and may effectively isolate nitrogen. The electron temperature rapidly lowers as a distance from the plasma generation part increases. Nitrogen ions in the plasma are transported to and near the substrate 2 through diffusion, and accelerated by ion sheath and collide with the substrate 2. After one minute passes, the pressure of the plasma process chamber 1 is held at the second pressure, such as 400 Pa. After additional two minutes pass, the microwave power supply stops and supply of nitrogen gas stops. After the plasma process chamber 1 is vacuum-exhausted below 0.1 Pa, the substrate 2 is fed outside the plasma process chamber 1. The temperature of the substrate 2 has been heated by plasma up to 270° C.

The nitrogen concentration in the silicon oxide film on the surface of the substrate 2 drastically reduces from the depth of 1 nm when measured by SIMS, and exhibited 0.4 atm % or less at an interface between the silicon oxide film and silicon at a depth of 2 nm. According to the SIMS measurement principle, the actual nitrogen concentration at the interface between the silicon oxide film and silicon is considered to be lower than this value. According to the XPS measurement, the nitrogen concentration surface density increases up to about 5 atm%, which is larger than the case where the pressure is not varied during processing. Nitrogen combines with Si into Si₃N when it is measured by the XPS. According to the measurement using an ellipsometer, optical oxide film converted thickness uniformity was 3%.

The controller 21 controls the pressure of the plasma process chamber 1 by controlling the pressure regulating valve 25a, such as a Vakuumventile A.G. (“VAT”) manufactured gate valve that has a pressure regulating function and a MKS Instruments, Inc. (“MKS”) manufactured exhaust slot valve, so that the pressure sensor 24 for detecting the pressure of the process chamber 1 exhibits a predetermined value, while driving the vacuum pump 25b.

Since nitrogen is injected into the silicon oxide film while the substrate 2 is maintained at a temperature that prevents nitrogen from dispersing in the silicon oxide film, nitrogen stays at the injected position. The dispersion active energy of nitrogen atoms in the silicon oxide film is supposed to be 0.7 to several eV according to experiments by the instant inventors. In other words, although it depends upon the nitrogen concentration gradient in the silicon oxide film and process time, nitrogen injected into the silicon oxide film stays at the site when the temperature of the substrate is maintained approximately about 400° C. or smaller. If the substrate 2 is at such high temperature as about 800° C., nitrogen injected into the silicon oxide film disperses towards the interface between the silicon oxide film, and deteriorates the device characteristics. Preferably, the low temperature does not cause such problem.

On the other hand, the substrate 2 is maintained at a temperature that provides an anneal effect, thereby recovering a lattice defect derived from injections of nitrogen ions. This temperature (or the temperature that reduces the defect density below a permissible value) is about 200° C. or higher according to experiments by the instant inventors.

Therefore, the temperature maintained between 200° C. and 400° C. prevents nitrogen from dispersing in the silicon oxide film and provides an anneal effect. The substrate 2 is heated by the heater 4 and the nitrogenion irradiation. The substrate 2 is heated by the heater 4 before the nitriding process so that the temperature of the substrate 2 becomes between 200° C. and 400° C.

The temperature of the substrate 2 may be measured directly (for example, by a direct contact with a thermocouple, etc.) or indirectly (for example, by a thermometer embedded in the stage 3 to measure the temperature of the stage 3 or by radiant heat from the substrate 2 to reflect its temperature). The present invention does not preclude the thermometer to use the thermocouple that directly contacts the substrate 2 and measures its temperature, but the direct contact generally might cause contamination. The temperature control mechanism includes the controller 21, a thermometer 22, (heater lines of) the heater 4, and a power supply 23 connected to the controller 21. The controller 21 controls electrification to the heater 4 so that the temperature of the substrate 2 becomes between 200° C. and 400° C.

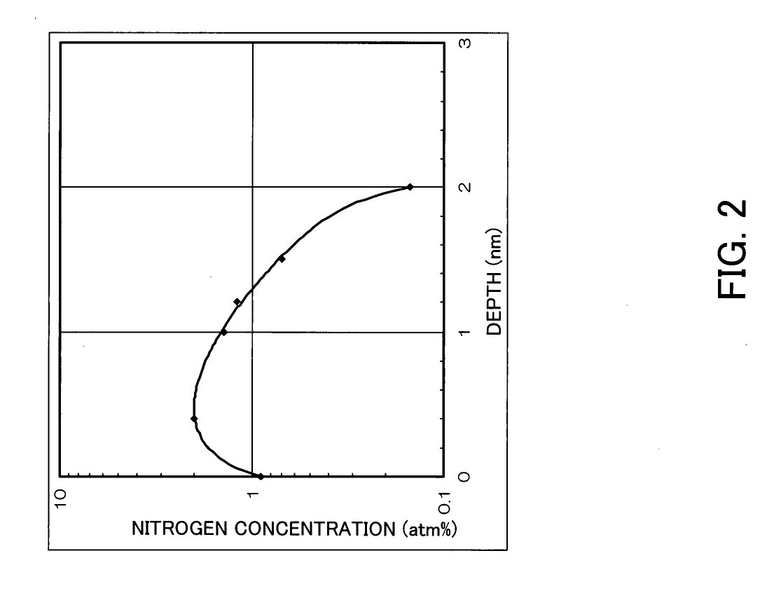

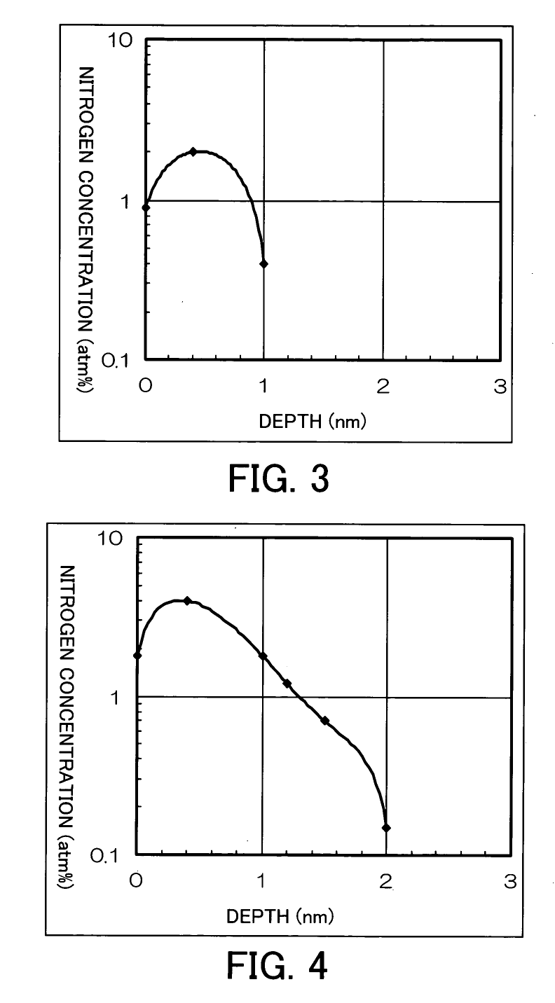

The pressure in the plasma process chamber 1 is maintained to be the first pressure, and the nitride concentration distribution in the silicon oxide film is formed as shown in FIG. 2. The pressure in the plasma process chamber 1 is maintained to be the second pressure, and the nitride concentration distribution in the silicon oxide film is formed as shown in FIG. 3. A nitride concentration distribution in the silicon oxide film may be formed as shown in FIG. 4 by combining the above nitride concentration distributions in the silicon oxide film with each other. In other words, nitrogen is injected into a relatively deep position in the silicon oxide film at the first pressure, and nitrogen is injected onto the surface of the silicon oxide film which has low concentration as a result of the first pressure. As a result, the nitrogen concentration increases from the midsection to the surface without increasing the nitrogen density at the interface between the silicon oxide film and silicon. Careful selections of process time, process pressure and the process change times would be able to maintain approximately constant the nitrogen concentration from the surface to the midsection in the silicon oxide film.

A change of the plasma electron temperature near the substrate 2 once during the nitriding process by changing a pressure in the plasma process chamber 1 would form a desired nitrogen concentration distribution in the silicon oxide film.

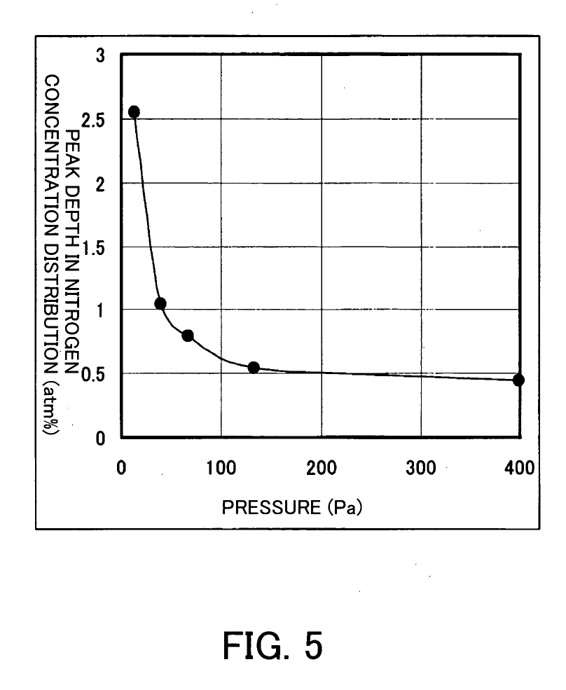

There is a relationship between the pressure in the plasma process chamber 1 and the nitrogen concentration distribution peak depth as shown in FIG. 5. The plasma electron temperature lowers due to collisions as the pressure becomes higher. In addition, the irradiation energy of nitrogen ions is given by the following equation that regards nitrogen ions as ions that are incident upon a sufficiently large insulator, and proportional to the electron temperature. Therefore, a change of the pressure in the plasma process chamber 1 would change the plasma electron temperature and the irradiation energy of nitrogen ions, whereby the desired nitrogen concentration distribution is obtained in the silicon oxide film:

e·Vw=−k·Te·ln(0.654·(mi/me)^{0.5}) (1)

where “e·Vw” is the irradiation energy of nitrogen ions, “e” is elementary electric charge, “Vw” is potential of the substrate (suppose that plasma potential is 0 V), “k” is Boltzmann's constant, “Te” is electron temperature, “mi” is ion mass, and “me” is electron mass.

The microwave surface-wave interference plasma processing apparatus shown in FIG. 1 generates plasma electron temperature of 1 to 2 eV near the substrate 2, and maintains the nitrogen concentration distribution peak below 1 nm. Therefore, the apparatus is favorable to a nitriding process of an extremely thin oxide film.

The nitriding process using the microwave surface-wave plasma processing apparatus has been disclosed in Japanese Patent No. 2,925,535, but this reference does not disclose various conditions for the nitriding process to an extremely thin oxide film, such as a method for changing once the electron temperature during the process.

In comparison with the nitriding process of another manner of remote plasma, this method uses microwave surface-wave plasma that has high nitrogen-ion density and low electron temperature, and may advantageously not only reduce damages to the substrate 2 but also shorten the process time.

Second Embodiment

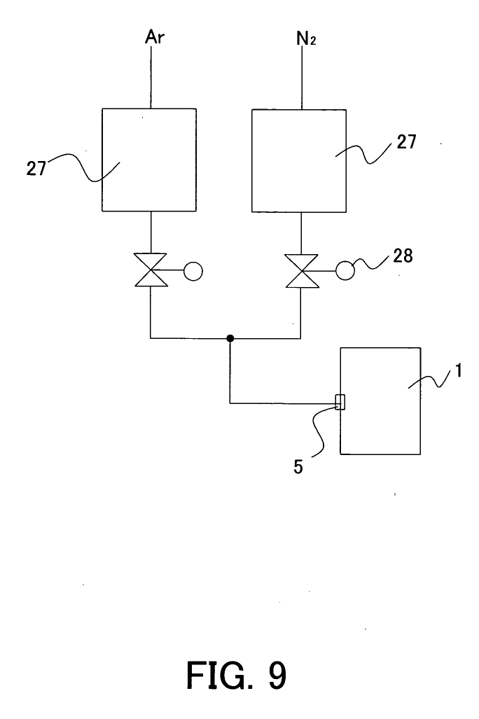

A description will now be given of a second embodiment according to the present invention, with reference to FIGS. 1 and 9. The second embodiment varies a mixture ratio of gas to be introduced into the plasma process chamber and changes the electron temperature once during the nitriding process, thereby nitriding the silicon oxide film. In other words, after the silicon oxide film is nitrided to its midsection using only nitrogen plasma, argon is added to lower the plasma electron temperature to nitride a surface of the silicon oxide film. This manner increases the nitrogen concentration from the midsection to the surface in the silicon oxide film without increasing nitrogen concentration in the interface between silicon and the silicon oxide film. An addition of inert gas, such as argon gas, tends to increase the electron density and lower the electron temperature because the electron density increases for the invariant energy total amount and consequently the electron temperature for each electron lowers.

The plasma process is conducted using microwave surface-wave interference plasma processing apparatus shown in FIG. 1 as follows: First, the heater 4 heats the substrate stage 3 up to 200° C. Then, the substrate 2 that forms a silicon oxide film having a thickness of 2 nm on its surface is fed to and placed on the stage 3. Next, the plasma process chamber 1 is vacuum-exhausted by the exhaust system 25. Then, nitrogen gas is introduced into the plasma process chamber 1 at 200 sccm through the process gas introducing means 5. Then, the pressure regulating valve 25a, such as a conductance valve, provided in the exhaust system 25 is regulated so as to hold the pressure in the plasma process chamber 1 to 130 Pa. The microwave power supply supplies the plasma process chamber 1 with microwaves of 1.5 kW through the slot-cum non-terminal circle waveguide 8 and dielectric window 7, thereby generating plasma in the plasma process chamber 1. After one minute passes, argon gas of 50 sccm and nitrogen of 150 sccm are introduced into the plasma process chamber 1. After additional three minutes pass, the microwave power supply stops and supply of nitrogen gas stops. After the plasma process chamber 1 is vacuum-exhausted below 0.1 Pa, the substrate 2 is fed outside the plasma process chamber 1. The temperature of the substrate 2 has been heated up by plasma, but the temperature was below 300° C.

The nitrogen concentration in the silicon oxide film on the surface of the substrate 2 drastically reduces from the depth of 1 nm when measured by SIMS, and exhibited 0.5 atm % or less at an interface between the silicon oxide film and silicon at a depth of 2 nm. According to the SIMS measurement principle, the actual nitrogen concentration at the interface between the silicon oxide film and silicon is considered to be lower than this value. According to the XPS measurement, the nitrogen concentration increases up to about 5 atm %, which is larger than the case where a gas mixture ratio is not varied during processing.

As shown in FIG. 9, the flow rate of argon gas and nitrogen gas may be regulated using a mass flow controller 27, as manufactured by MKS, which is connected to the controller 21 and controls the mass flow of the gas, and a valve 28 for stopping supplying gas to the plasma process chamber 1. The controller 21 supplies gas of a desired mixture ratio to the plasma process chamber 1 by directing the desired mass flow to the mass flow controller 27. Alternatively, it closes the valve 28 when not flowing gas at all. Instead of argon gas, other insert gas, such as krypton and xenon may be used. The insert gas is not reactive and thus does not negatively affect the silicon oxide film. In addition, it is easily ionized, increases the plasma density, and fastens the nitriding process speed.

Third Embodiment

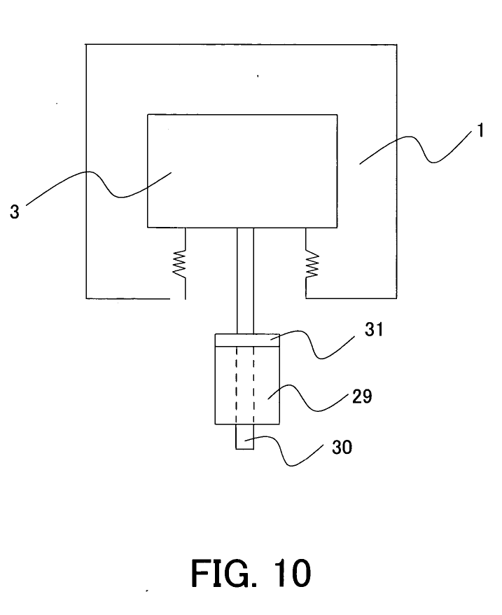

A description will now be given of a third embodiment according to the present invention, with reference to FIGS. 1 and 10. The third embodiment ascends and descends the substrate stage 3 through an elevator mechanism 29 and changes the electron temperature once during the nitriding process, thereby nitriding the silicon oxide film. In other words, after the substrate 2 is moved close to the dielectric window 7 to nitride the silicon oxide film down to its midsection, the substrate 2 is moved apart from the dielectric window 7 to lower the plasma electron density near the substrate 2 and nitride the surface of the silicon oxide film. This manner maintains approximately constant the nitrogen concentration from the midsection to the surface in the silicon oxide film without increasing the nitrogen concentration in the interface between silicon and the silicon oxide film. In FIG. 10, 29 is the elevator mechanism, connected to and controlled by the controller 21, for moving up and down the stage 3. 30 is a support rod fixed on the stage 3 and moved up and down by the elevator mechanism 29. 31 is a vertical position detector for detecting a position of the stage 3. The elevator mechanism 29 moves up and down the support rod 30 using a rotation of a gear attached to a pneumatic drive rotary machine (not shown). The up-and-down position detector may use, for example, a potentiometer known in the art. The controller 21 controls the elevator mechanism 29 so that a vertical position of the stage 3 detected by the vertical position detector 31 is a desired position.

The plasma process is conducted using microwave surface-wave interference plasma processing apparatus shown in FIG. 1 as follows: First, the heater 4 heats the substrate stage 3 up to 100° C. Then, the substrate 2 that forms a silicon oxide film having a thickness of 2 nm on its surface is fed to and placed on the stage 3. Then, the substrate stage 3 is moved up to a position 5 cm below the dielectric window 7 using elevator means (not shown). Next, the plasma process chamber 1 is vacuum-exhausted by the exhaust system 25. Then, nitrogen gas is introduced into the plasma process chamber 1 at 200 sccm through the process gas introducing means 5. Then, the pressure regulating valve 25a, such as a conductance valve, provided in the exhaust system 25 is regulated so as to hold the pressure in the plasma process chamber 1 to 400 Pa. Then, the microwave power supply supplies the plasma process chamber 1 with microwaves of 1.5 kW through the slot-cum non-terminal circle waveguide 8 and dielectric window 7, thereby generating plasma in the plasma process chamber 1. After one minute passes, the microwave power supply is stopped and the substrate stage 3 is moved to a position 10 cm below the dielectric window 7. Then, the microwave power supply supplies the plasma process chamber 1 with microwaves of 1.5 kW. After additional two minutes pass, the microwave power supply stops and supply of nitrogen gas stops. After the plasma process chamber 1 is vacuum-exhausted below 0.1 Pa, the substrate 2 is fed outside the plasma process chamber 1. The temperature of the substrate 2 has been heated up by plasma, but the temperature was below 300° C.

The nitrogen concentration in the silicon oxide film on the surface of the substrate 2 drastically reduces from the depth of 1 nm when measured by SIMS, and exhibited 0.5 atm % or less at an interface between the silicon oxide film and silicon at a depth of 2 nm. According to the SIMS measurement principle, the actual nitrogen concentration at the interface between the silicon oxide film and silicon is considered to be lower than this value. According to the XPS measurement, the nitrogen concentration increases up to about 8 atm %, which is larger than the case where the substrate stage is not moved during processing.

Fourth Embodiment

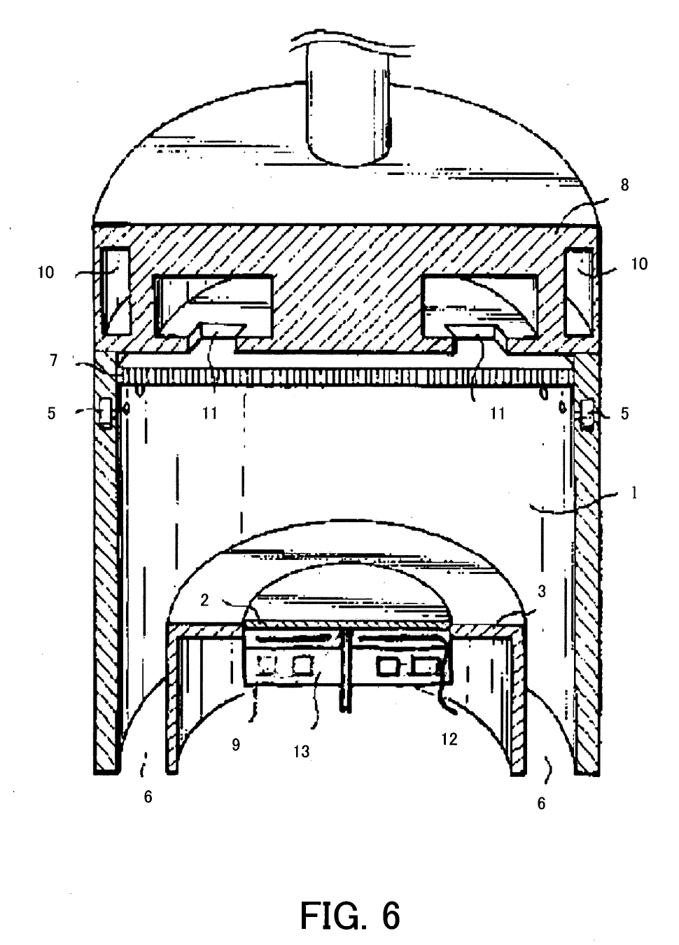

A description will now be given of a fourth embodiment according to the present invention, which uses a microwave surface-wave interference plasma processing apparatus shown in FIG. 6. The fourth embodiment provides the substrate stage with a mechanism for cooling the substrate 2 to cool the same. Cooling of the substrate 2 mitigates temperature rise in the plasma process and maintains the substrate 2 at a temperature that not only substantially prevents nitrogen from dispersing but also provides an anneal effect. 9 is a cooling channel for cooling the substrate stage 3. 12 is a dipole absorption electrode that generates electrostatic absorptive power between the substrate stage 3 and the substrate 2. A helium supply inlet 13 and a dent that is connected to it and has a depth of 100 μm are provided on the surface of the substrate stage 3. Those elements which are the same as corresponding elements in FIG. 1 are designated by the same reference numerals and a detailed description will be omitted.

The plasma process is conducted using microwave surface-wave interference plasma processing apparatus shown in FIG. 6 as follows: First, cooling water is flowed through the cooling channel 9 to maintain the substrate stage 3 at the room temperature. Then, the substrate 2 that forms a silicon oxide film having a thickness of 2 nm on its surface is fed to and placed on the stage 3. Then, the voltage of ±200 V is applied to the dipole absorptive electrode 12 from the high voltage power supply (not shown) to absorb the substrate 2 onto the substrate stage 3. Next, helium is filled in the dent in the surface of the stage 3 through the helium supply inlet 13. The temperature of the substrate 2 may be adjusted by properly selecting the pressure of helium in a range of 0 to 2000 Pa and adjusting the coefficient of thermal conductivity of helium. The instant embodiment set the pressure of helium to 800 Pa. Then, the substrate stage 3 is moved up to a position 5 cm below the dielectric window 7 using elevator means (not shown). Next, the plasma process chamber 1 is vacuum-exhausted by the exhaust system 25. Then, nitrogen gas is introduced into the plasma process chamber 1 at 200 sccm through the process gas introducing means 5. Then, the pressure regulating valve 25a, such as a conductance valve, provided in the exhaust system 25 is regulated so as to hold the pressure in the plasma process chamber 1 to 400 Pa. Then, the microwave power supply supplies the plasma process chamber 1 with microwaves of 1.5 kW through the slot-cum non-terminal circle waveguide 8 and dielectric window 7, thereby generating plasma in the plasma process chamber 1. After three minutes pass, the microwave power supply is stopped and the substrate stage 3 is moved to a position 10 cm below the dielectric window 7. Then, the microwave power supply supplies the plasma process chamber 1 with microwaves of 1.5 kW. After additional two minutes pass, the microwave power supply stops and supplies of nitrogen gas and helium stop. After the plasma process chamber 1 is vacuum-exhausted below 0.1 Pa, supply of the high voltage to the absorptive electrode 12 stops and the substrate 2 is fed outside the plasma process chamber 1. The temperature of the substrate 2 has been heated up by plasma, but the temperature was below 250° C.

The nitrogen concentration in the silicon oxide film on the surface of the substrate 2 drastically reduces from the depth of 1 nm when measured by SIMS, and exhibited 0.5 atm % or less at an interface between the silicon oxide film and silicon at a depth of 2 nm. According to the SIMS measurement principle, the actual nitrogen concentration at the interface between the silicon oxide film and silicon is considered to be lower than this value. According to the XPS measurement, the nitrogen concentration increases up to about 15 atm %, which is larger than the case where the substrate stage is not moved during processing.

Fifth Embodiment

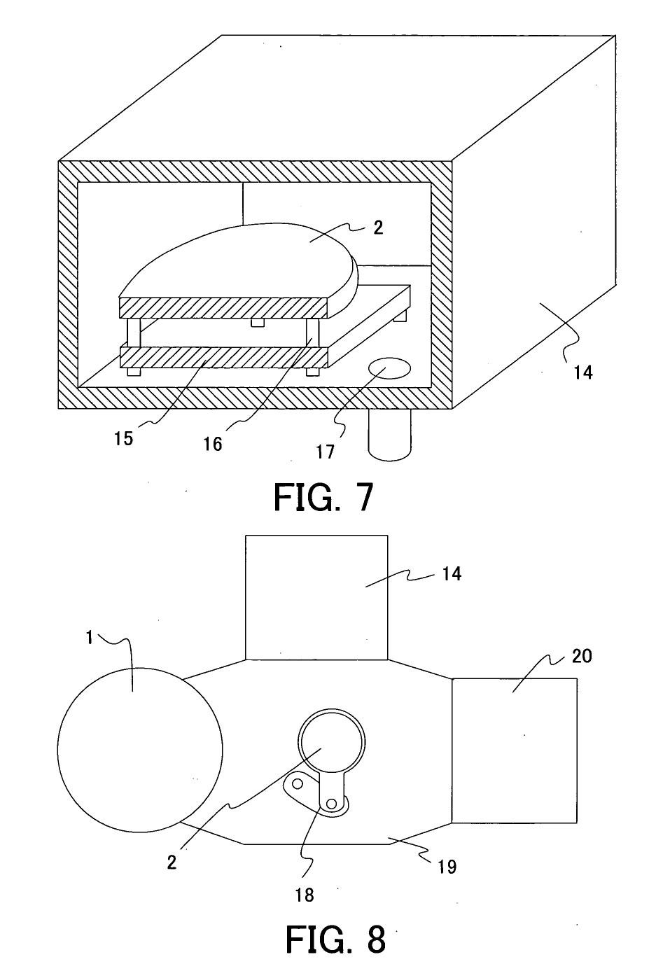

A description will now be given of the fifth embodiment according to the present invention, with reference to FIGS. 6 to 8. The fifth embodiment preheats and then nitrides the substrate 2. The preheat promotes reactions between the substrate 2 and nitrogen, and effectively increases the nitrogen concentration. This embodiment uses the preheat chamber 14 shown in FIG. 7 and the microwave surface-wave interference plasma processing apparatus shown in FIG. 6. In FIG. 7, 14 is the preheat chamber, 15 is an aluminum nitride ceramic heater, 16 is a support rod for holding the substrate 2, and 17 is an exhaust opening for vacuum-exhausting the preheat chamber 14. In FIG. 8, 18 is a feeder for feeding the substrate 2, and 20 is a port for mounting the substrate 2. The plasma process chamber 1, preheat chamber 14, and port 20 are connected to a vacuum-exhausted feed chamber 19 by means (not shown) as shown in FIG. 8. Each chamber is isolated by a gate (not shown).

In preheating, the preheat chamber 14 is vacuum-exhausted by the exhaust system 25 down to 0.1 Pa or less, and the ceramic heater 15 is heated up to 300° C. Next, the substrate 2 is mounted on the support rod 16. After three minutes pass, the substrate 2 is fed into the plasma process chamber 1 from the preheat chamber 14 by the feeder 18, followed by the same nitriding process as that in the fourth embodiment.

While the above embodiments describe an injection of nitrogen into the silicon oxide film, an injected material is not limited to nitrogen and may effectively use B, P, As, O, etc. In addition, the present invention is applicable to an injection to such a substrate as Si, Al, Ti, Zn, Ta, etc. in addition to the silicon oxide film.

Thus, the above embodiments provide a substrate modification method that may sufficiently reduce the nitrogen at the interface between silicon and silicon oxide film, enhance the nitrogen concentration in the silicon oxide film, and generate high-quality silicon oxynitride film in a short process time. In other words, the above embodiments may generate high-quality silicon oxynitride film in which the nitrogen concentration is enhanced from the midsection to the surface in the silicon oxide film, in a short process time, without increasing the nitrogen concentration at the interface between silicon and the extremely thin silicon oxide film. In addition, impurity of high concentration may be injected into only the surface of the substrate in a short process time.

What is claimed is:

1. A method for modifying a surface of a substrate to be processed, by utilizing microwave surface-wave plasma, said method comprising the steps of:
maintaining a temperature of the substrate to a temperature which substantially prevents a material injected by a plasma process into the substrate from diffusing in the substrate, and provides an anneal effect;
introducing process gas including the material into a plasma process chamber;
generating plasma in the plasma process chamber; and
changing at least once an electron temperature of the plasma.

2. A method according to claim 1, wherein said changing step changes a pressure of the plasma process chamber.

3. A method according to claim 1, wherein said changing step changes a mixture ratio of the process gas introduced into the plasma process chamber.

4. A method according to claim 1, wherein said changing step changes a distance between a generation part for generating the plasma and a stage for mounting the substrate to be processed.

5. A method for modifying a surface of a substrate to be processed by utilizing process gas that includes a predetermined material, and microwave surface-wave plasma, said method comprising the steps of:
turning the process gas into the plasma, injecting the plasma into the substrate, and forming at least two concentration distributions of the material on the surface of the substrate; and
maintaining a temperature of the substrate to one which prevents the material from diffusing beyond a predetermined depth in the substrate, and which maintains defect density of the substrate below a permissible value.
